(19) United States
(12) Patent Application Publication
(10) Pub. No.: US 2018/0174874 A1
(43) Pub. Date: Jun. 21, 2018

(54) WAFER CARRIER HAVING A DOOR WITH A UNITARY BODY

(71) Applicant: Entegris, Inc., Billerica, MA (US)

(72) Inventors: Murali Bandreddi, Colorado Springs, CO (US); Matthew A. Fuller, Colorado Springs, CO (US)

(21) Appl. No.: 15/736,411

(22) PCT Filed: Jun. 14, 2016
(86) PCT No.: PCT/US2016/037311

§ 371 Date: Dec. 14, 2017

Related U.S. Application Data
(60) Provisional application No. 62/175,834, filed on Jun. 15, 2015.

(51) Int. Cl. H01L 21/673

(52) U.S. Cl. CPC H01L 21/67389; H01L 21/67373; H01L 21/67376

(57) ABSTRACT

A front opening wafer carrier includes: a container portion. The container portion includes a top wall, a bottom wall, a pair of side walls, a back wall, and a door frame opposite the back wall, the door frame defining a front opening, and a door removably received in the door frame for closing the front opening. The door has a single body construction and a substantially smooth exterior surface including one or more automation interface receiving features having a minimal volume, which may minimize the amount of oxygen that can be trapped between the wafer carrier door and an equipment front end module when the wafer carrier is in use.

### RELATED APPLICATION

This application claims the benefit of and priority to U.S. Provisional Application No. 62/175,834 filed on Jun. 15, 2015, the entirety of which is incorporated herein by reference for all purposes.

### TECHNICAL FIELD

The disclosure relates generally to wafer carriers and more particularly to the door of such wafer carriers.

### BACKGROUND

Semiconductor wafers are subjected to numerous steps during processing. This usually entails transporting a plurality of wafers between workstations or facilities for processing. Semiconductor wafers are delicate and easily damaged by physical contact or shock and by static electricity. Further semiconductor manufacturing processes are extremely sensitive to contamination by particulates or chemical substances. Consequently, as a way to reduce the deleterious effect of contaminants on wafers, specialized containers have been developed to minimize the generation of contaminants and to isolate wafers from contaminants exterior to the containers. These containers typically include a removable door with gasketing or other means for providing a tight seal of the door with the container body. Exemplary containers include front opening unified pods (FOUPs), front opening shipping boxes (FOSBs), and Multi-application carriers (MACs), where the door closes a front opening of the container.

As semiconductors have become smaller in scale, that is, as the number of circuits per unit area has increased, contaminants in the form of particulates consequently have become more problematic. The size of particulates that can destroy a circuit has decreased and is approaching the molecular level. Thus, better particulate control is desirable during all phases of manufacturing, processing, transporting, and storage of semiconductor wafers. Additionally, as circuit geometries become smaller, it becomes important to process wafers in a low oxygen environment.

Oxygen can be controlled within a wafer carrier such as, for example, a FOUP, using inert purge and likewise within an inert equipment front end module (EFEM) by maintaining a low oxygen environment. However, and with reference to FIG. 1, due to the method of construction of known FOUP doors, oxygen can become trapped in the cavity 2 that houses the latching mechanism 6 defined between the FOUP door cover 10 and base 12. As such, when the door of a docked FOUP is removed by a load port, the trapped oxygen can escape, momentarily increasing the oxygen concentration within the EFEM and therefore, potentially damaging circuit geometry.

### SUMMARY

This disclosure relates generally to wafer carriers and more particularly to the door of such wafer carriers. In one illustrative embodiment, a front opening wafer carrier includes a container portion including a top wall, a bottom wall, a pair of side walls, a back wall, and a door frame opposite the back wall, the door frame defining a front opening, and a door removably received in the door frame for closing the front opening. The door has a single body construction and a substantially smooth exterior surface which can minimize the amount of oxygen that can be trapped between the wafer carrier and an equipment front end module when the wafer carrier is in use.

In another illustrative embodiment, a wafer container includes: a container portion having a front opening; and a door configured to sealingly engage with the container portion. The door has a single body construction and includes a substantially flat exterior surface and an interior surface, the exterior surface including one or more recessed automation interface features and the interior surface comprising one or more recesses formed therein. The wafer container further includes a gasket extending around a periphery of the door, the gasket engaging the container portion when the door is received in the front opening of the container portion to hermetically seal the container portion.

In yet another illustrative embodiment, a method of minimizing trapped oxygen between a wafer carrier and an equipment front end module having a door includes docking a wafer carrier on a load port adjacent an opening of the equipment front end module, opening the door of the equipment front end interface module; and disengaging the door from the container portion of the wafer carrier. The wafer carrier includes a container portion and a door. The door has a single body construction and includes an exterior surface and an interior surface. The exterior surface is substantially flat and includes one or more recessed automation interface features. The interior surface includes one more ribs providing structural support to the door. The substantially flat exterior surface having the recessed automation features minimizes oxygen and other gases trapped between the wafer carrier and the equipment front end module which may damage electronic circuitry. The door does not require a mechanical latching mechanism.

The preceding summary is provided to facilitate an understanding of some of the innovative features unique to the present disclosure and is not intended to be a full description. A full appreciation of the disclosure can be gained by taking the entire specification, claims, drawings, and abstract as a whole.

### BRIEF DESCRIPTION OF THE DRAWINGS

The disclosure may be more completely understood in consideration of the following description of various illustrative embodiments in connection with the accompanying drawings, in which:

FIG. 1 is a perspective view of a known FOUP having a door including a cover and a base.

FIG. 2 is a perspective view of a FOUP in accordance with embodiments of the disclosure.

FIG. 3 is a front view of a FOUP door in accordance with the disclosure.

FIGS. 4A and 4B are rear views of the FOUP door shown in FIG. 3 in accordance with embodiments of the disclosure.

FIG. 5 is an exploded rear view of the FOUP door shown in FIG. 4B.

FIG. 6 is a schematic view of a wafer carrier interacting with an equipment front end module.

FIG. 7 illustrates process steps for minimizing trapped oxygen between a wafer carrier and an EFEM in accordance with embodiments of the disclosure.

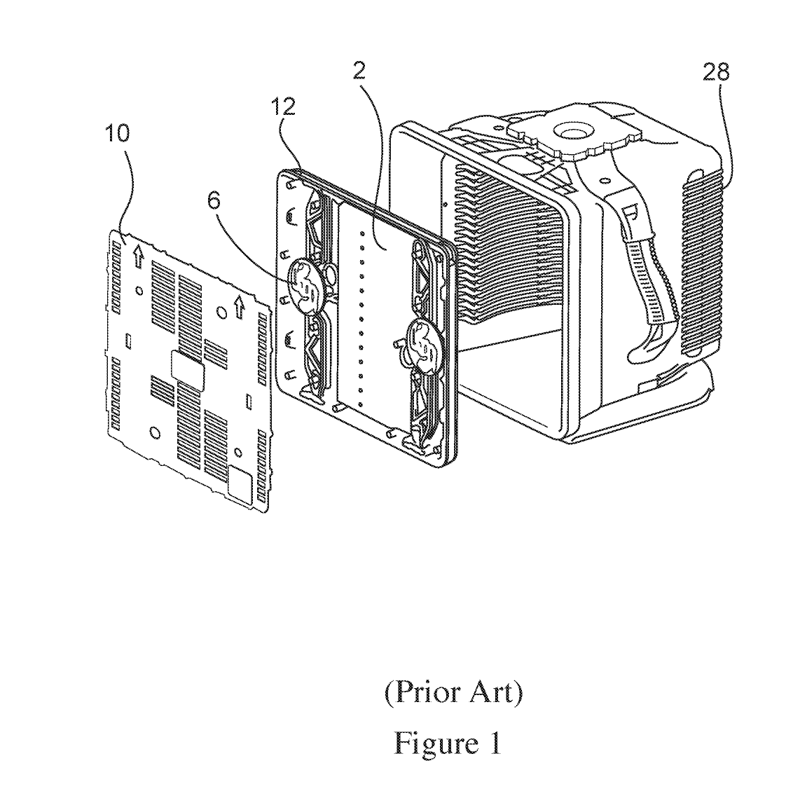

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The following detailed description should be read with reference to the drawings in which similar elements in different drawings are numbered the same. The detailed description and the drawings, which are not necessarily to scale, depict illustrative embodiments and are not intended to limit the scope of the invention. The illustrative embodiments depicted are intended only as exemplary. Selected features of any illustrative embodiment may be incorporated into an additional embodiment unless clearly stated to the contrary.

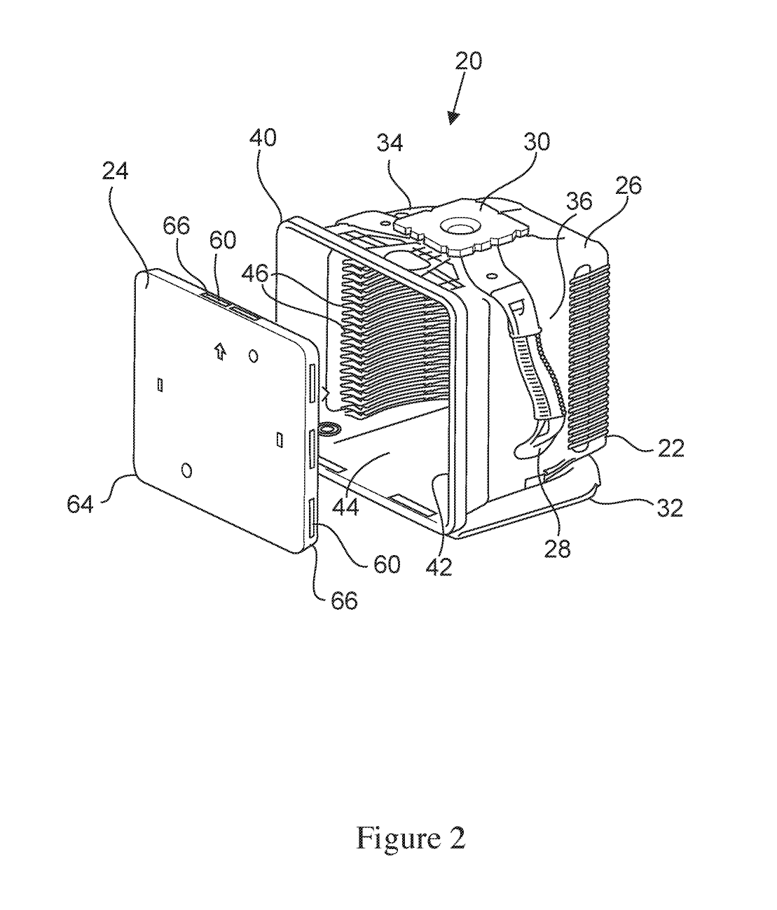

FIG. 2 illustrates an exemplary wafer container 20. The wafer container 20 shown in FIG. 2 is a FOUP. While the embodiments described herein are described in the context of a FOUP, it will be generally understood by those of skill in the art that many of the concepts disclosed herein may have applicability to other wafer containers and more particularly other front opening wafer containers.

As shown in FIG. 2, the wafer container includes a container portion 22 and a door 24. The container portion includes a top 26 with a robotic flange 30, a bottom 32 having kinematic coupling plate (not shown), a left side 34, a right side 36, and a door frame 40 defining a door opening 42 leading to an open interior 44 with wafer shelves 46 for supporting a number of semiconductor wafers. The door 24 is configured to sealingly engage with the door frame 40 of the container portion 22 to maintain a hermetically sealed environment within the wafer container 20 when the door 24 is engaged with the container portion 22. A pair of side handles 28 may be provided on the left and right sides 34, 36 of the container portion 22 so that the container 20 may be picked up and manually moved by a person.

The wafer container 20 may be made from a variety of thermoplastic polymeric materials and more particularly, a thermoplastic polymer that is designed to minimize particle shedding. In some cases, the wafer container 20 may include an electronic barrier material or electrostatic dissipative material. A portion if not all of the wafer container 20 can be injection molded.

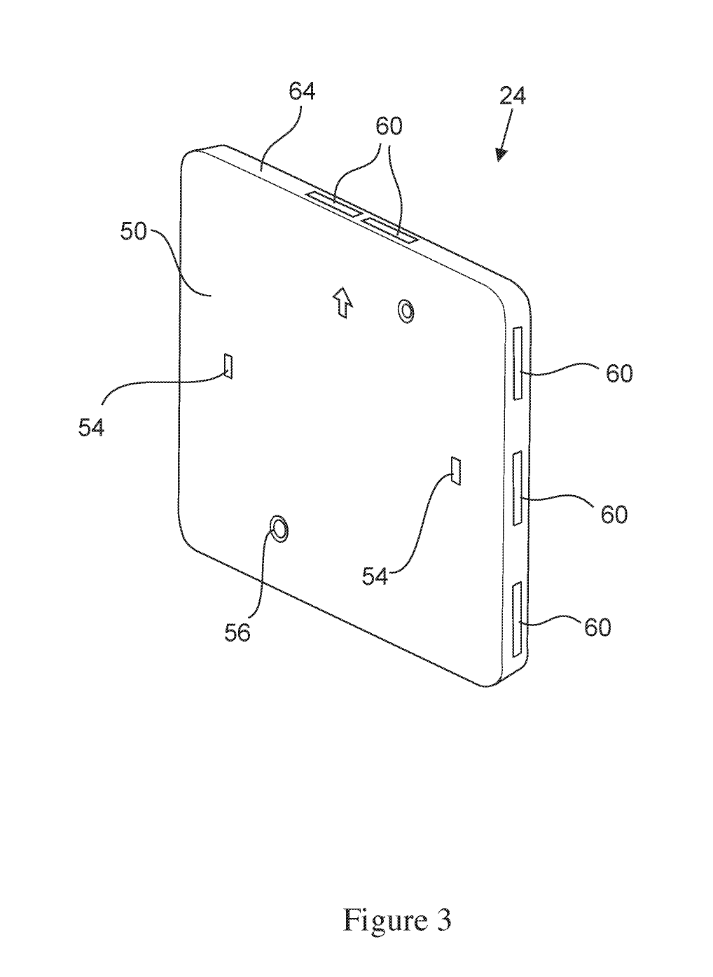

FIG. 3 provides a front, close-up view of an exemplary door 24. The door 24 can be injection molded or machined, and can be formed of the same or different material as the container portion 22. According to various embodiments of the disclosure, the door 24 has a single piece, unitary body construction including a substantially flat or smooth exterior surface 50 that is configured to minimize the amount of oxygen that can be trapped between the wafer container door 24 and the EFEM when the FOUP is docked on a load port. The exterior surface 50 of the door 24 includes only those automation equipment interface features that are needed to interface with the automation equipment. Exemplary automation equipment interface features include key holes 54 and a door pin socket 56. The key holes 54 are formed such that they are capable of interface with SEMI standard keys, and the door pin socket 56 is formed such that it is capable of interfacing with SEMI standard door pins. A flat surface surrounds the key holes 54 and socket 56 to allow the exterior surface 50 of the door to interface with SEMI standard vacuum cups.

The automation equipment interface features 54, 56 are formed in the outer surface 50 of the door 24 such that they provide the minimum volume required to interface with the automation equipment. The automation equipment interface features 54, 56 may be formed by removing material from the door through machining or coring, or they may be formed during injection molding of the door 24. In some cases, the key holes 54 are cored out from the rear side of the door such that they are able to permit rotation of the SEMI standard key in the hole. The rear side of the key hole may include a cap or a plug, as will be described in greater detail herein. Providing a substantially flat or smooth exterior surface 50 and minimizing the volume of the automation equipment features formed in the outer surface 50 of the door 24 can decrease the volume of oxygen and other gases that can become trapped between the door 24 of wafer container 20 and the EFEM when the wafer container 20 is docked on a load port. Minimizing the amount of trapped oxygen and other gases lowers the amount of oxygen and other gases that may be released into the EFEM when the door 24 is removed from the wafer container 20.

Referring again to FIG. 3, in some embodiments, as will be described in greater detail herein, the door 24 can include a plurality of magnets 60 distributed about the door perimeter 64 which form a portion of a magnetic latching system that can be used to secure the door 24 to the container portion 22. The container portion 22 may include a corresponding number of magnets or ferrous containing features that are configured to interact with the magnets 60 provided around the door perimeter 64. In some cases, the magnets 60 are received in individual pockets or slots 66 provided in the door perimeter 64.

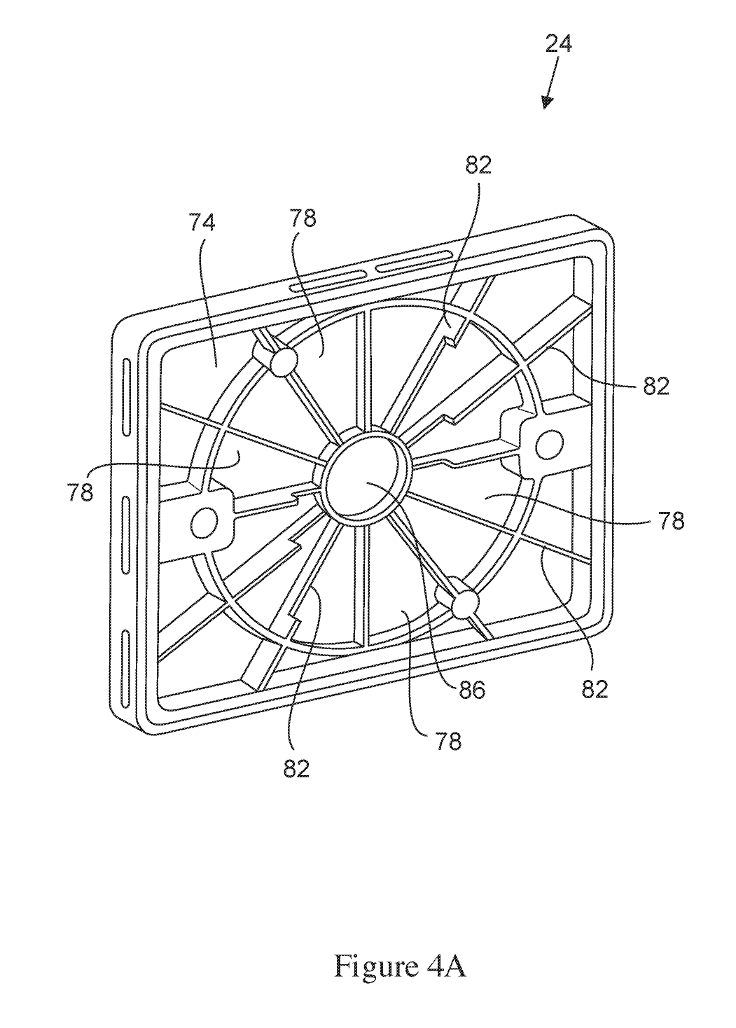

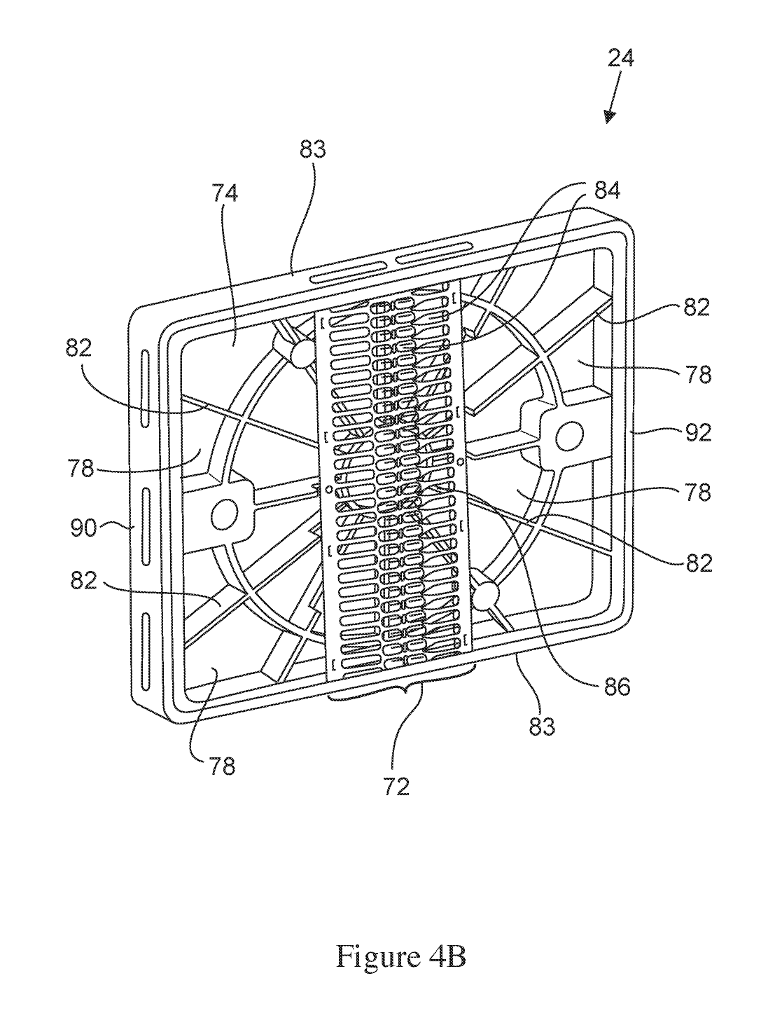

FIGS. 4A and 4B show each provide rear views of the door 24 in accordance with different embodiments of the disclosure. FIG. 4A shows an embodiment of the door 24 in which a wafer cushion is not included, while FIG. 4B shows an embodiment of the door 24 in which a wafer cushion 72 is provided on the rear side 74 of the door 24. As shown in each of FIGS. 4A and 4B, the door cavity has been eliminated and a plurality of recesses 78 are be formed in the rear side 74 of the door. In some cases, the recesses 78 can be formed by removing material away from the rear side of the door such as by machining or coring. In other cases, the recesses 78 can be formed during injection molding of the door. The recesses 78 define one or more ribs 82.

The ribs 82 structurally support the door 24 and minimize potential warping of the door. In some embodiments, as shown in FIGS. 4A and 4B, the ribs 82 are defined by the recesses 78 such that they extend radially outward from a center 86 of the door 24 and have a spoke or wagon wheel configuration. This is just one example. It will be generally understood that recesses 78 and ribs 82 can have other configurations. For example, a plurality of recesses 78 and ribs 82 may form a grid along the rear side 74 of the door 24. In other examples, the recesses 78 and ribs 82 may extend horizontally or vertically along the rear side 74 of the door 24. In still yet another example, the recesses 78 and ribs 82 may form concentric rings. In some cases, as shown, the door also does not include a mechanical latching mechanism.

In some embodiments, as shown in FIG. 4B, a wafer cushion 72 including a plurality of wafer engaging portions 84 can be provided on the rear side 74 of the door 24. In some cases, the wafer cushion 72 is received and retained in a recess formed in the rear side 74 of the door. The wafer cushion 72 can be retained on the rear side 74 of the door 24 by snap-fit, press-fit, interference fit or other retention means. As shown in FIG. 4B, the wafer cushion 72 extends from the top 83 of the door 24 to the bottom 85 of the door 24 and is centrally positioned with respect to the left and right sides 90, 92 of the door 24.

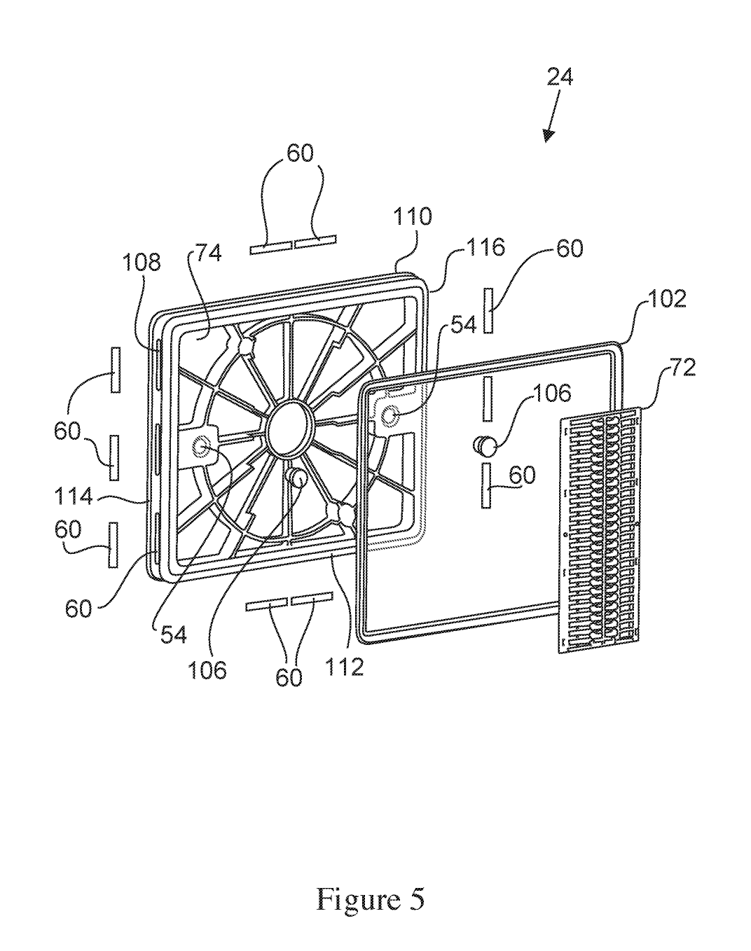

FIG. 5 is an exploded view of the door 24 shown in FIG. 4B. Some additional features of the door 24 are more readily visible in FIG. 5. This includes a seal 102 which extends around a periphery of the door 24 and the plurality of magnets 60, introduced earlier with reference to FIG. 3. Also more readily visible in FIG. 5, are one or more plugs 106 or covers that may be used to seal, cap or otherwise close the rear of the one or more automation interface features (e.g. 54) formed in the exterior surface of the door 24, as disclosed herein. In some embodiments, as can be seen in FIG. 5, the door does not include a door cavity and also does not include a mechanical latching mechanism. Eliminating the door cavity also may minimize the amount of oxygen that becomes trapped in the door. The door also does not include a mechanical latching mechanism. Instead, the plurality of magnets 60 are used to secure the door 24 to the container body.

As shown in FIG. 5, the door 24 can include a seal 102 sometimes also referred to as a gasket retained in a seal receiving groove that extends inwardly into the door adjacent the door periphery (not shown). The seal receiving groove faces the interior of the container portion when the door is received in the door frame. The groove is generally configured as a channel with a bottom seating surface, two opposing side surfaces, and an upper ledge portion or shoulder that is configured to retain the seal 102 in the groove. In many cases, the seal 102 is formed of a thermoplastic or thermoset elastomer which may have a Shore A hardness of 40-80 durometer. The seal 102 helps to maintain the hermetically sealed environment within the wafer carrier when the door 24 is engaged with the container portion.

In addition to the seal 102, the door 24 can include a magnetic latching system defined by a plurality of magnetic elements 60 distributed about a periphery of the door. Each door side may include a single magnetic element or multiple magnetic elements 60. The magnetic elements 60 may incorporate a variety of magnetic materials known to those of skill in the art, and may interact with a corresponding magnetic element or ferrous counterpart provided on the container portion to secure the door 24 within the door frame, thus closing and effectively sealing the wafer container. In addition, at least some of the magnetic elements 60 can include ferrous shielding around at least a portion of the magnetic element to shield block or shield the magnetic field from projecting in an undesired direction and to focus the magnetic energy in another direction such as, for example towards a corresponding magnetic element provide on the container portion. In some cases, as shown, each of the top 110, bottom 112, left and right sides 112, 114 of the door 24 includes two or more magnetic elements 60. In some cases, the magnetic elements 60 may be spaced an equal distance from one another about the periphery of the door 24, but this is not required. In other cases, for example, the magnetic elements 60 can be grouped together such that they are centered along the respective top 110 and bottom 112 of the door 24, and spaced an equal distance from one another along the sides 114, 116 of the door 24, as shown.

The magnetic elements 60 may be received in a plurality of corresponding channels or slots 108 sized to receive and retain the magnetic elements 60. The magnetic elements 60 may be secured in the slots 108 with a cover (not shown). Examples of suitable securing methodologies may include snap-fitting, laser-welding, or ultrasonically welding the cover into place over the magnetic elements 60. The door 24, incorporating the magnetic elements 60, can be opened with a SEMI standard load port.

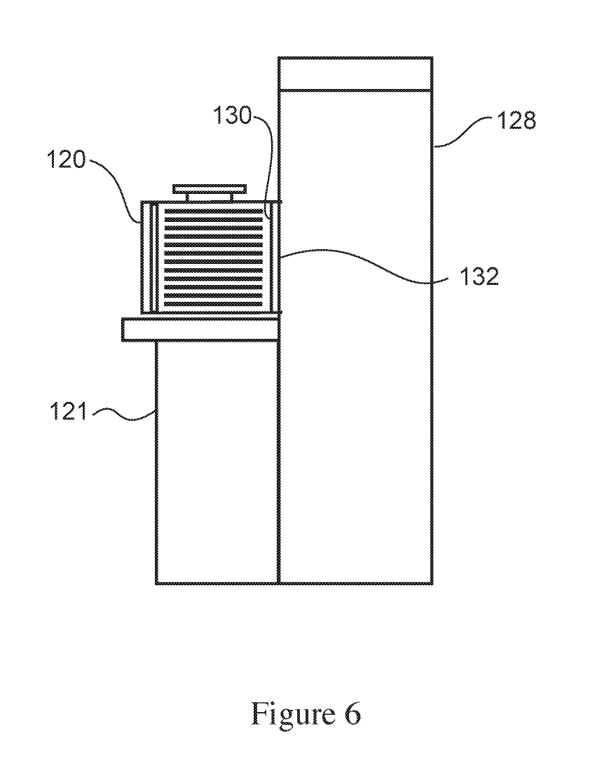

FIG. 6 is a schematic drawings showing a wafer carrier 120 docked on a load port 124 adjacent an equipment front end module 128. As discussed herein, the wafer carrier may be any front opening wafer carrier such as, for example, a FOUP, FOSB, or MAC. When the wafer carrier 120 is docked on the load port 124 there may be a small gap between the wafer carrier door 130 and the EFEM door 132. Oxygen and/or other gases may be trapped in this gap. To minimize the amount of oxygen and other gases that may be trapped, the door 124 of the wafer carrier 120 is configured such that it has a single body construction and substantially flat or smooth exterior surface that faces the EFEM, as described herein according to the various embodiments. The single body construction of the door 130 along having a substantially flat exterior surface including recessed automation features having a minimal volume can minimize oxygen trapped between the wafer carrier and the equipment front end module thus, preventing possible damage to the electronic circuitry contained within the EFEM.

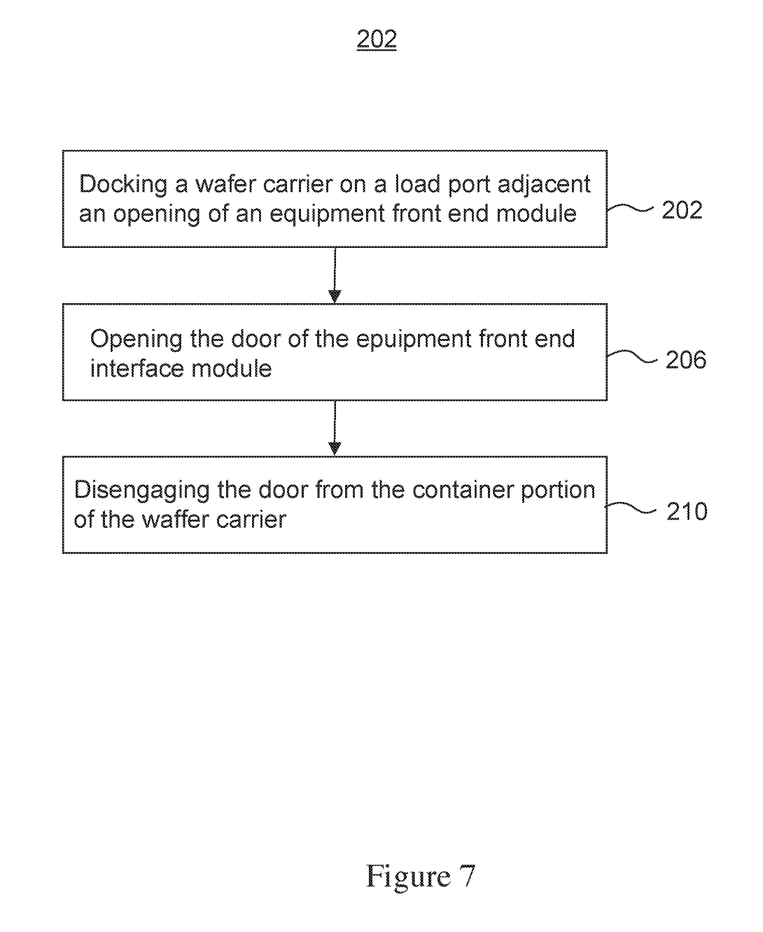

FIG. 7 outlines a method 200 including process steps 202, 206 and 210 for minimizing trapped oxygen between a wafer carrier and an EFEM in accordance with embodiments of the disclosure. In use, the wafer carrier is docked on the load port (Block 202), and the door of the EFEM is opened (Block 206). Next, the door is disengaged from the wafer carrier by SEMI standard automation equipment allowing the EFEM to access the semiconductor wafers contained within the wafer carrier for processing (Block 210). The amount of oxygen and other gases that may be trapped between the wafer carrier and the EFEM may be minimized. Minimal oxygen trapping may be attributed to the door having a substantially flat or smooth exterior surface that faces outwardly in a direction towards the EFEM, and automation equipment features having a minimal volume formed in the door's outer surface. Minimizing the amount of trapped oxygen and other gases lowers the amount of oxygen and other gases that may be released into the EFEM when the door is removed from the wafer container.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respect, only illustrative. Changes may be made in details, particularly in matters of shape, size, and arrangement of parts without exceeding the scope of the disclosure. The disclosure's scope is, of course, defined in the language in which the appended claims are expressed

1. A front opening wafer carrier comprising:
a container portion including a top wall, a bottom wall, a pair of side walls, a back wall, and a door frame opposite the back wall, the door frame defining a front opening; and
a door removably received in the door frame for closing the front opening, the door having a single body construction and including a substantially flat first surface facing in a direction outwardly from the front opening and an opposing second surface, the first surface including one or more recessed automation interface features and the second surface comprising one or more recesses formed therein, wherein the door minimizes oxygen trapped between the wafer carrier and an equipment front end module.

2. The wafer carrier according to claim 1, wherein the door further comprises at least one automation interface feature formed in the exterior surface of the door.

3. The wafer carrier according to claim 2, wherein the at least one automation interface feature is recessed from the exterior surface of the door.

4. The wafer carrier according to claim 2, wherein the at least one automation interface feature is a key hole.

5. The wafer carrier according to claim 2, wherein the at least one automation interface feature is a door pin socket.

6. The wafer carrier according to claim 1, wherein the door comprises a plurality of ribs formed on an interior surface of the door.

7. The wafer carrier according to claim 6, wherein the plurality of ribs extends radially outward from a center portion of the door.

8. The wafer carrier according to claim 1, further comprising an elastomeric seal extending around a periphery of the door, the elastomeric seal engaging structure on the door frame when the door is received in the door frame to hermetically seal the enclosure portion.

9. The wafer carrier according to claim 1, further comprising a wafer cushion disposed on a rear side of the door.

10. The wafer carrier according to claim 1, further comprising a plurality of magnets distributed about a door perimeter and configured to interact with corresponding elements provided about an inner perimeter of the door frame.

11. The wafer carrier according to claim 1, wherein the door does not include a mechanical latching mechanism.

12-17. (canceled)

18. A method of minimizing trapped oxygen between a wafer carrier and an equipment front end module having a door, the method comprising:
docking a wafer carrier on a load port adjacent an opening of the equipment front end module, the wafer earner comprising a container portion and a door, the door having a single body construction and comprising a first surface and a second surface, the first surface being substantially flat and facing in a direction toward the opening of the equipment front end module and including one or more recessed automation interface features and the second surface comprising one more ribs providing structural support to the door; opening the door of the equipment front end interface module; and
disengaging the door from the container portion of the wafer carrier.

19. The method of claim 18, wherein the door does not include a mechanical latching mechanism.
